(19) United States
(12) Patent Application Publication
(10) Pub. No.: US 2024/0162189 A1
(43) Pub. Date: May 16, 2024

(54) Active Interposers For Migration Of Packages

(71) Applicant: Altera Corporation, San Jose, CA (US)

(72) Inventors: Hon Khet Chuah, Penang (MY); Archanna Srinivasan, San Jose, CA (US); Arch Zaliznyak, San Mateo, CA (US); Guang Chen, San Jose, CA (US); Kok Kee Looi, Penang (MY)

(73) Assignee: Altera Corporation, San Jose, CA (US)

(21) Appl. No.: 18/392,162

(22) Filed: Dec. 21, 2023

(51) Int. Cl. H01L 25/065; H01L 23/00; H03K 17/00

(52) U.S. Cl. CPC H01L 25/0652; H01L 24/16; H01L 2224/16145; H01L 2224/16225; H03K 17/005

(57) ABSTRACT

An active interposer device includes a multiplexer circuit configurable to provide a first signal from a first integrated circuit to an external terminal of the active interposer device in a first configuration of the active interposer device. The multiplexer circuit is further configurable to provide a second signal from a second integrated circuit to the external terminal in a second configuration of the active interposer device. The second integrated circuit is larger than the first integrated circuit, and the active interposer device is configurable to couple the first integrated circuit or the second integrated circuit to a package substrate through the external terminal.

### TECHNICAL FIELD

The present disclosure relates to active interposers, and more particularly, to active interposers and methods for facilitating migration of packages between integrated circuits.

### BACKGROUND

Configurable integrated circuits (ICs) can be configured by users to implement desired custom logic functions. In a typical scenario, a logic designer uses computer-aided design (CAD) tools to design a custom circuit design. When the design process is complete, the computer-aided design tools generate configuration data. The configuration data is then loaded into configuration memory elements that configure configurable logic circuits in the integrated circuit to perform the functions of the custom circuit design.

### BRIEF DESCRIPTION OF DRAWINGS

FIG. 1A is a diagram that illustrates an example of an integrated circuit package that includes an integrated circuit, an active interconnection device, and a package substrate.

FIG. 1B is a diagram that illustrates an example of an integrated circuit package that includes the active interconnection device and the package substrate of FIG. 1A and another integrated circuit.

FIG. 2 is a diagram that illustrates an example of an integrated circuit package that includes an active interconnection device having a multiplexer circuit with three data inputs.

FIG. 3 is a diagram that illustrates an example of an integrated circuit package that includes an active interconnection device having four multiplexer circuits.

FIG. 4A is a diagram that illustrates an example of a portion of an integrated circuit package that includes an active interconnection device having 16 multiplexer circuits.

FIG. 4B is a diagram that illustrates an example of a portion of another integrated circuit package that includes the active interconnection device and the package substrate of FIG. 4A and another integrated circuit.

FIG. 5 is a diagram that illustrates an example of a configurable logic integrated circuit (IC) that can be the integrated circuit disclosed herein with respect to any of FIG. 1A, 1B, 2, 3, 4A, or 4B.

FIG. 6A illustrates a block diagram of a system that can be used to implement a circuit design to be programmed onto a programmable logic device using design software.

FIG. 6B is a diagram that depicts an example of a programmable logic device that includes three fabric die and two base die that are connected to one another via microbumps.

FIG. 7 is a block diagram illustrating a computing system configured to implement one or more aspects of the embodiments disclosed herein.

### DETAILED DESCRIPTION

An integrated circuit (IC) package typically includes an integrated circuit die (also referred to as an integrated circuit) and a package substrate. The integrated circuit die is mounted on and coupled to the package substrate. The package substrate is configured to couple the integrated circuit die to a circuit board through conductors in the package substrate and conductive bumps and balls. Each package substrate is designed to be coupled to an integrated circuit die having a particular size. A package substrate is typically not designed to be coupled to integrated circuit dies having different sizes at the same connections on the package substrate.

In some applications, it may be desirable to use an integrated circuit package with an integrated circuit die having a different size than the die size that the integrated circuit package was originally designed for. As an example, a user may desire to migrate integrated circuit packages to larger integrated circuit dies. In this example, the integrated circuit packages were originally designed for smaller size integrated circuit dies. As part of the migration, the package substrates in the integrated circuit packages are coupled to integrated circuit dies having larger sizes. Thus, it may be desirable for an integrated circuit package to be configurable to couple integrated circuits of different sizes to a circuit board.

In other applications, an integrated circuit package is migrated to a new integrated circuit die that has the same bump mapping and dimensions as the original integrated circuit die for the package. Migration of an integrated circuit package to a new integrated circuit die typically involves using the same map and dimensions of conductive balls that couple the package to a circuit board, but the routing in the package is changed to match the different floorplan of the new integrated circuit die.

For example, an integrated circuit package can be migrated from an original integrated circuit die to a new integrated circuit die, even if the integrated circuit dies have input/output (IO) blocks that are placed at different locations. The routing in the package substrate is changed to accommodate the different arrangement of the IO blocks in the two integrated circuit dies. A different package substrate is built to route the IO blocks to the same balls that are coupled to the circuit board to implement the migration from the original integrated circuit die to the new integrated circuit die. Thus, a different package substrate is designed and built in previously known systems to implement each migration of a package to a different integrated circuit die having a unique arrangement of IO blocks. Therefore, it would be desirable to provide a solution to reduce the cost of designing package substrates for migrating packages to different integrated circuit dies. The positions of the connections of the package substrate to the circuit board through conductive balls is fixed before and after migration. Migration of an integrated circuit package can also facilitate the migration of input/output (IO) interfaces, such as double-date rate (DDR) interfaces, streaming interfaces, etc.

According to some examples disclosed herein, multiplexing can be used to accommodate couplings through an interposer between integrated circuit dies of different sizes and conductive balls coupled between a package substrate and a circuit board. According to these examples, an active interconnection device includes multiplexer circuits that are configurable to couple different external terminals on a first surface of the active interconnection device to external terminals on a second surface of the active interconnection device. The second surface is on the opposite side of the active interconnection device relative to the first surface. The multiplexer circuits are configurable to couple integrated circuit dies of different sizes to the same conductive balls through a package substrate in an integrated circuit package without changing the routing of conductors in the package substrate. In addition, the multiplexer circuits are configurable to couple IO blocks that are at different locations in different integrated circuit dies to the same conductive balls through a package substrate without changing the routing of conductors in the package substrate. The multiplexer circuits disclosed herein can, as examples, be implemented by logic gates or lookup tables. Examples of the multiplexer circuits are disclosed in the drawings and the description herein, which are provided as examples and are not intended to be limiting.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) logic integrated circuits, such as field programmable gate arrays (FPGAs). As discussed herein, an integrated circuit (IC) can include hard logic and/or soft logic. The circuits in an integrated circuit device (e.g., in a configurable logic IC) that are configurable by an end user are referred to as “soft logic.” “Hard logic” generally refers to circuits in an integrated circuit device that have substantially less configurable features than soft logic or no configurable features.

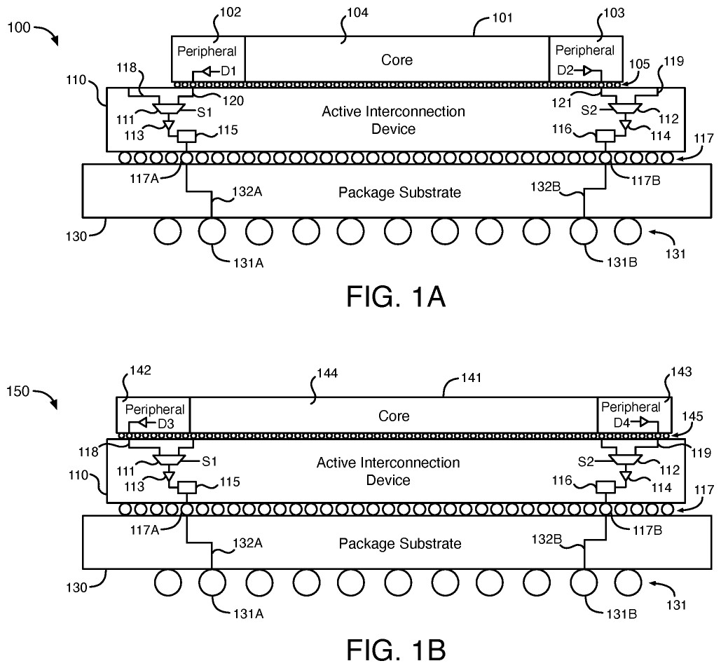

FIGS. 1A-1B are diagrams that illustrate an example of an active interconnection device 110 that can couple a package substrate 130 in integrated circuit packages to integrated circuit (IC) dies 101 and 141 having different sizes. Figure (FIG.) 1A illustrates an example of an integrated circuit package 100 that includes integrated circuit die 101, active interconnection device 110, and package substrate 130. FIG. 1B illustrates an example of an integrated circuit package 150 that includes integrated circuit die 141, active interconnection device 110, and package substrate 130.

IC die 101 includes peripheral regions 102-103 and a core region 104. IC die 141 includes peripheral regions 142-143 and a core region 144. Each of the integrated circuit (IC) dies 101 and 141 can be any type of IC die, such as a configurable IC (e.g., a field programmable gate array (FPGA) or programmable logic device), a microprocessor IC, a graphics processing unit IC, a memory IC, an application specific IC, a transceiver IC, a memory IC, etc. IC die 101 is coupled to active interconnection device 110 through conductive bumps 105 in IC package 100 of FIG. 1A. IC die 141 is coupled to active interconnection device 110 through conductive bumps 145 in IC package 150 of FIG. 1B. Active interconnection device 110 is coupled to package substrate 130 through conductive bumps 117 in each of the IC packages 100 and 150. Package substrate 130 in each of the IC packages 100 and 150 can be coupled to a circuit board (not shown) through conductive balls 131.

IC die 101 is smaller (in width and/or length) than IC die 141. The active interconnection device 110 can be utilized, for example, to migrate IC package 100 having the smaller IC 101 to IC package 150 having the larger IC 141 so that IC die 141 is coupled to the same conductive balls 131 as IC 101, without having to change the routing of conductors in the package substrate 130. Active interconnection device 110 can be, for example, an active interposer.

The active interconnection device 110 includes multiplexer circuits 111-112, output buffer circuits 113-114, and electrostatic discharge (ESD) circuits 115-116. Multiplexer circuits 111-112 are configurable by select signals S1-S2, respectively, to provide selected input signals to the multiplexer outputs. Multiplexer circuit 111 is configurable by select signal S1 to couple one of two different external terminals on a top surface of active interconnection device 110 to an external terminal on a bottom surface of active interconnection device 110 at conductive bump 117A through output buffer circuit 113 and ESD circuit 115. Multiplexer circuit 112 is configurable by select signal S2 to couple one of two different external terminals on the top surface of active interconnection device 110 to an external terminal on the bottom surface of active interconnection device 110 at conductive bump 117B through output buffer circuit 114 and ESD circuit 116. The select signals S1-S2 can be stored in memory or storage circuits (e.g., fuses, random access memory (RAM), flip-flops. etc.) in active interconnection device 110 or ICs 101 and 141 and provided to multiplexer circuits 111-112 through conductors (also referred to as wires). The select signals S1-S2 can be generated within ICs 101 and 141 or by software running on an external computing system, as examples. As a more specific example, the select signals S1-S2 that control multiplexer circuits 111-112, respectively, can be generated and controlled by a computer-aided design (CAD) software tool used to design a custom circuit design for IC die 101.

In IC package 100 of FIG. 1A, a signal D1 from the peripheral region 102 of IC 101 is provided through one of the bumps 105 and through a fixed connection conductor 120 in the active interconnection device 110 to a first data input of the multiplexer circuit 111. Multiplexer circuit 111 is configured by select signal S1 to provide signal D1 to output buffer circuit 113. Output buffer circuit 113 provides signal D1 as received from multiplexer circuit 111 through ESD circuit 115, conductive bump 117A, and conductor 132A in package substrate 130 to conductive ball 131A for transmission through the circuit board.

Also, in IC package 100 of FIG. 1A, a signal D2 from the peripheral region 103 of IC 101 is provided through another one of the bumps 105 and through a fixed connection conductor 121 in active interconnection device 110 to a first data input of multiplexer circuit 112. Multiplexer circuit 112 is configured by select signal S2 to provide signal D2 to output buffer circuit 114. Output buffer circuit 114 provides signal D2 as received from multiplexer circuit 112 through ESD circuit 116, conductive bump 117B, and conductor 132B in package substrate 130 to conductive ball 131B for transmission through the circuit board.

The states of the select signals S1-S2 can be changed to reconfigure the multiplexer circuits 111-112 to migrate IC package 100 of FIG. 1A to IC package 150 of FIG. 1B so that IC die 141 is coupled to the same conductive balls 131 as IC die 101, without having to change the routing of conductors in the package substrate 130. As discussed above, IC die 141 is larger than IC die 101.

As a result, in IC package 150 of FIG. 1B, a signal D3 is provided from the peripheral region 142 of IC 141 through one of the bumps 145 and through a fixed connection conductor 118 in active interconnection device 110 to a second data input of multiplexer circuit 111. Multiplexer circuit 111 is configured by select signal S1 to provide signal D3 to output buffer circuit 113. Output buffer circuit 113 provides signal D3 as received from multiplexer circuit 111 through ESD circuit 115, conductive bump 117A, and conductor 132A in package substrate 130 to conductive ball 131A for transmission through the circuit board.

Also, in IC package 150 of FIG. 1B, a signal D4 is provided from the peripheral region 143 of IC 141 through another one of the bumps 145 and through a fixed connection conductor 119 in active interconnection device 110 to a second data input of multiplexer circuit 112. Multiplexer circuit 112 is configured by select signal S2 to provide signal D4 to output buffer circuit 114. Output buffer circuit 114 provides signal D4 as received from multiplexer circuit 112 through ESD circuit 116, conductive bump 117B, and conductor 132B in package substrate 130 to conductive ball 131B for transmission through the circuit board.

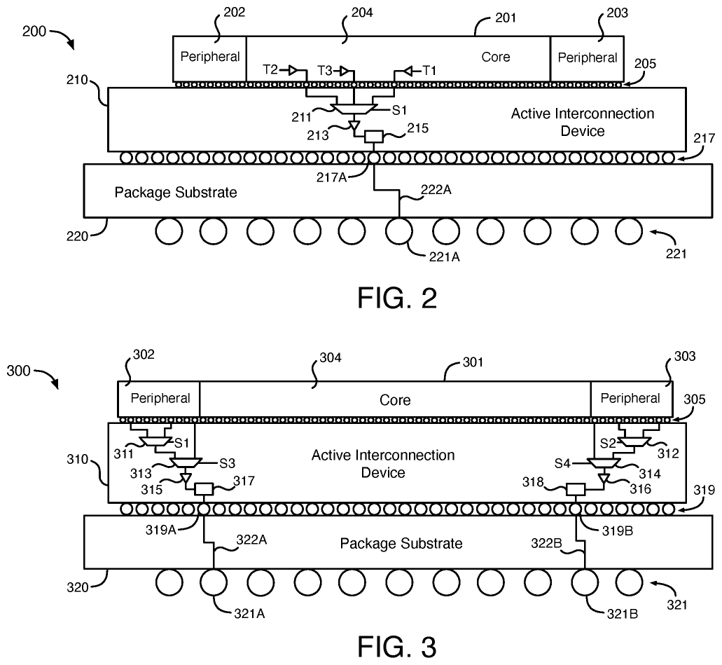

FIG. 2 is a diagram that illustrates an example of an integrated circuit package 200 that includes an active interconnection device 210 having a multiplexer circuit 211 with 3 data inputs. The integrated circuit (IC) package 200 includes an integrated circuit (IC) die 201, the active interconnection device 210, and package substrate 220. IC die 201 includes peripheral regions 202-203 and a core region 204.

IC die 201 can be any type of IC die, such as a configurable IC (e.g., FPGA or programmable logic device), a microprocessor IC, a graphics processing unit IC, a memory IC, an application specific IC, a transceiver IC, a memory IC, etc. IC die 201 is coupled to active interconnection device 210 through conductive bumps 205 in IC package 200. Active interconnection device 210 is coupled to package substrate 220 through conductive bumps 217 in IC package 200. Package substrate 220 can be coupled to a circuit board (not shown) through conductive balls 221.

Active interconnection device 210 includes multiplexer circuit 211, output buffer circuit 213, and ESD circuit 215. Multiplexer circuit 211 is configurable by a select signal S1 to couple one of three different external terminals on a top surface of active interconnection device 210 to an external terminal on a bottom surface of active interconnection device 210 at conductive bump 217A through output buffer circuit 213 and ESD circuit 215. Active interconnection device 210 can be, for example, an active interposer.

During a test phase of IC die 201, test signals, such as test signals T1-T3, are generated inside IC die 201. The test signals, including test signals T1-T3, are transmitted from IC die 201 to an external test device outside IC package 200 for analysis and debugging purposes. The test signals T1, T2, and T3 are generated in the core region 204 of IC die 201 in three different time periods. The test signals T1, T2, and T3 are transmitted in the three different time periods to three data inputs of multiplexer circuit 211. Multiplexer circuit 211 is configurable by select signal S1 to provide the state of the active one of the test signals T1, T2, or T3 to output buffer circuit 213. Multiplexer circuit 211 can be reconfigured by changing the state of select signal S1 to provide the state of each of test signals T1, T2, and T3 to output buffer circuit 213 in the three different time periods. Output buffer circuit 213 buffers the state of the test signal T1, T2, or T3 received from multiplexer 211 to generate a buffered test signal that is provided through the ESD circuit 215, through bump 217A, and conductor 222A in package substrate 220 to conductive ball 221A for transmission through the circuit board. Select signal S1 can be stored in the active interconnection device 210, in IC die 201, or in an external device.

FIG. 3 is a diagram that illustrates an example of an integrated circuit package 300 that includes an active interconnection device 310 having four multiplexer circuits 311-314. The integrated circuit (IC) package 300 includes an integrated circuit (IC) die 301, the active interconnection device 310, and a package substrate 320. IC die 301 includes peripheral regions 302-303 and a core region 304.

IC die 301 can be any type of IC die, such as a configurable IC (e.g., an FPGA or programmable logic device), a microprocessor IC, a graphics processing unit IC, a memory IC, an application specific IC, a transceiver IC, a memory IC, etc. IC die 301 is coupled to active interconnection device 310 through conductive bumps 305 in IC package 300. Active interconnection device 310 is coupled to package substrate 320 through conductive bumps 319 in IC package 300. Package substrate 320 can be coupled to a circuit board (not shown) through conductive balls 321.

Active interconnection device 310 includes multiplexer circuits 311-314, output buffer circuits 315-316, and ESD circuits 317-318. Multiplexer circuits 311 and 313 are configurable by select signals S1 and S3 to couple one of three different external terminals on a top surface of active interconnection device 310 to an external terminal on a bottom surface of active interconnection device 310 at conductive bump 319A through output buffer circuit 315 and ESD circuit 317. Multiplexer circuits 312 and 314 are configurable by select signals S2 and S4 to couple one of three different external terminals on a top surface of active interconnection device 310 to an external terminal on a bottom surface of active interconnection device 310 at conductive bump 319B through output buffer circuit 316 and ESD circuit 318. Active interconnection device 310 can be, for example, an active interposer.

The data inputs of multiplexer circuit 311 are coupled through fixed connections in device 310 and two of conductive bumps 305 to two outputs of peripheral region 302. The first data input of multiplexer circuit 313 is coupled to the output of multiplexer circuit 311 through a fixed connection in device 310, and the second data input of multiplexer circuit 313 is coupled through a fixed connection in device 310 and one of conductive bumps 305 to a third output of peripheral region 302. Multiplexer circuits 311 and 313 are configurable by select signals S1 and S3, respectively, to provide a selected signal from peripheral region 302 to output buffer circuit 315. Output buffer circuit 315 provides the selected signal as received from multiplexer circuit 313 through ESD circuit 317, conductive bump 319A, and conductor 322A in package substrate 320 to conductive ball 321A for transmission through the circuit board.

The data inputs of multiplexer circuit 312 are coupled through fixed connections in device 310 and two of conductive bumps 305 to two outputs of peripheral region 303. The first data input of multiplexer circuit 314 is coupled to the output of multiplexer circuit 312 through a fixed connection, and the second data input of multiplexer circuit 314 is coupled through a fixed connection in device 310 and one of conductive bumps 305 to a third output of peripheral region 303. Multiplexer circuits 312 and 314 are configurable by select signals S2 and S4, respectively, to provide a selected signal from peripheral region 303 to output buffer circuit 316. Output buffer circuit 316 provides the selected signal as received from multiplexer circuit 314 through ESD circuit 318, conductive bump 319B, and conductor 322B in package substrate 320 to conductive ball 321B for transmission through the circuit board.

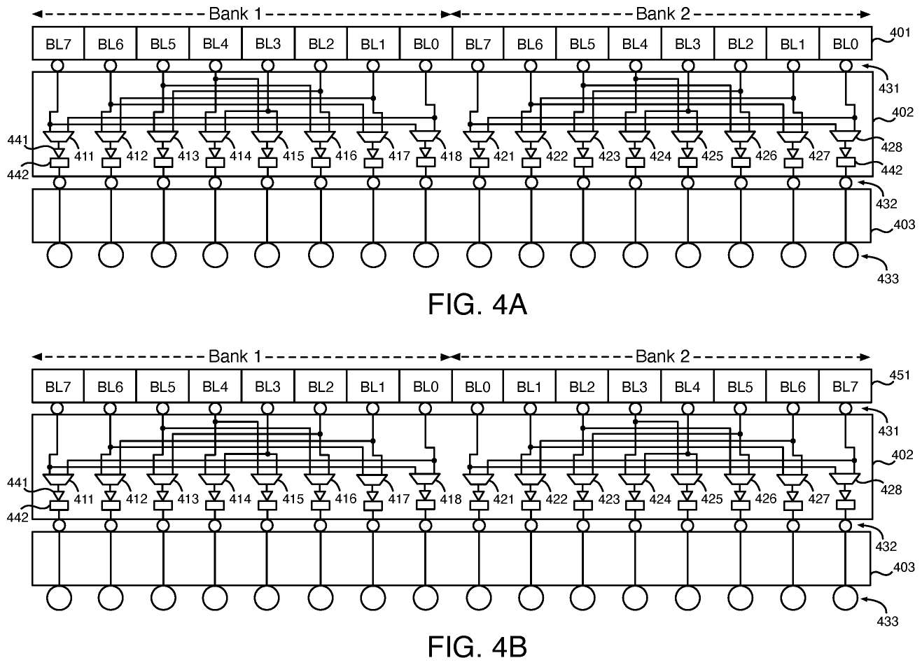

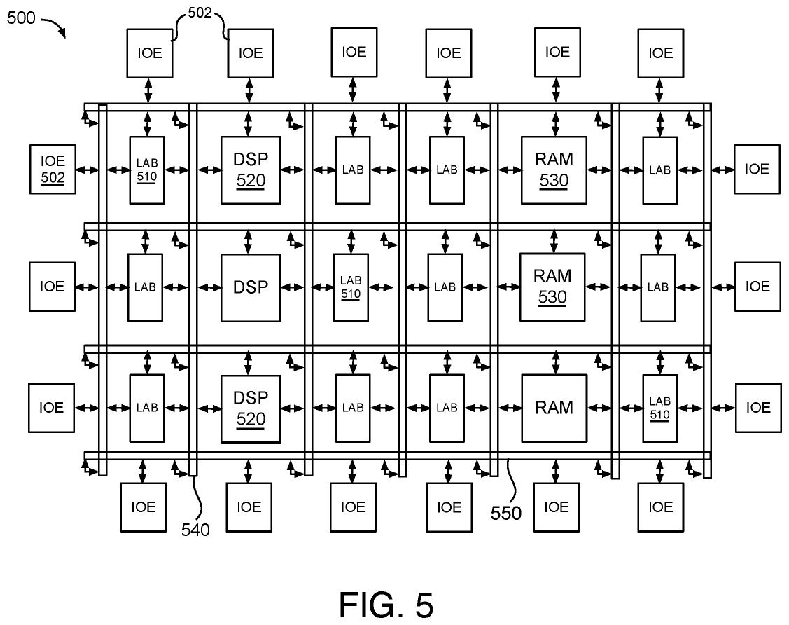

FIG. 4A is a diagram that illustrates an example of a portion of an integrated circuit package that includes an active interconnection device 402 having 16 multiplexer circuits 411-418 and 421-428. The integrated circuit package includes an integrated circuit die having 16 input/output (IO) circuit blocks 401 (e.g., that are part of a memory interface), the active interconnection device 402, and a package substrate 403. The 16 IO circuit blocks 401 are grouped into two banks that are identified as bank 1 and bank 2 in FIG. 4A. Each of the banks 1 and 2 includes 8 IO circuit blocks 401 that are labeled BL0-BL7 in FIG. 4A. Active interconnection device 402 includes multiplexer circuits 411-418 and 421-428, output buffer circuits 441, and ESD circuits 442. Active interconnection device 402 can be, for example, an active interposer.

The IC die of FIG. 4A can be any type of IC die, such as a configurable IC (e.g., an FPGA or programmable logic device), a microprocessor IC, a graphics processing unit IC, a memory IC, an application specific IC, a transceiver IC, a memory IC, etc. The IO circuit blocks 401 in the IC die are coupled to active interconnection device 402 through conductive bumps 431 in the IC package. Active interconnection device 402 is coupled to package substrate 403 through conductive bumps 432 in the IC package. Package substrate 403 can be coupled to a circuit board (not shown) through conductive balls 433.

Each of the multiplexer circuits 411-418 and 421-428 is configurable by a select signal (not shown) to provide an output signal from one of two different IO circuit blocks 401 to a corresponding one of the output buffer circuits 441 for transmission through a corresponding one of the ESD circuits 442, a corresponding one of the bumps 432, and package substrate 403 to a corresponding one of the balls 433. In the example of FIG. 4A, the multiplexer circuits 411-418 are configured to provide output signals from IO circuit blocks BL7, BL6, BL5, BL4, BL3, BL2, BL1, and BL0, respectively, in bank 1 to corresponding ones of the output buffer circuits 441. Also, in the example of FIG. 4A, the multiplexer circuits 421-428 are configured to provide output signals from IO circuit blocks BL7, BL6, BL5, BL4, BL3, BL2, BL1, and BL0, respectively, in bank 2 to corresponding ones of the output buffer circuits 441. The output buffer circuits 441 transmit the output signals received from the multiplexer circuits 411-418 and 421-428 through ESD circuits 442, bumps 432, and conductors in package substrate 403 to balls 433 for transmission through a circuit board.

The integrated circuit package of FIG. 4A can be migrated from an integrated circuit die having IO circuit blocks 401 to another integrated circuit die having input/output (IO) circuit blocks that are in different locations. The routing in the package substrate 403 is not changed. Instead, the multiplexer circuits 421-428 are reconfigured to couple the IO circuit blocks that are at different locations in the integrated circuit die to the same conductive balls 433 through package substrate 403 without changing the routing of the conductors in package substrate 403. An example of this configuration is shown in FIG. 4B.

FIG. 4B is a diagram that illustrates an example of a portion of an integrated circuit package that includes active interconnection device 402, package substrate 403, and an integrated circuit die. The integrated circuit die includes 16 input/output (IO) circuit blocks 451 (e.g., that are part of a memory interface) that are grouped into two banks that are identified as bank 1 and bank 2 in FIG. 4B. Each of the banks 1 and 2 includes 8 IO circuit blocks 451 that are labeled BL0-BL7 in FIG. 4B. The IO circuit blocks 451 in the IC die are coupled to active interconnection device 402 through conductive bumps 431 in the IC package. The IC die can be any type of IC die, such as a configurable IC (e.g., an FPGA or programmable logic device), a microprocessor IC, a graphics processing unit IC, a memory IC, an application specific IC, a transceiver IC, a memory IC, etc.

In the example of FIG. 4B, the order of the 8 IO circuit blocks 451 (BL0-BL7) in bank 2 are reversed relative to the order of the 8 IO circuit blocks 401 (BL7-BL0) in bank 2 of FIG. 4A. Therefore, in the example of FIG. 4B, multiplexer circuits 421, 422, 423, 424, 425, 426, 427, and 428 are reconfigured to provide output signals from IO circuit blocks BL7, BL6, BL5, BL4, BL3, BL2, BL1, and BL0, respectively, in bank 2 of IO circuit blocks 451 to corresponding ones of the output buffer circuits 441. The multiplexer circuits 411-418 in FIG. 4B have the same configuration as described above with respect to FIG. 4A. Thus, multiplexer circuits 411-418 are configured to provide output signals from IO circuit blocks BL7, BL6, BL5, BL4, BL3, BL2, BL1, and BL0, respectively, in bank 1 of IO circuit blocks 451 to corresponding ones of the output buffer circuits 441. The output buffer circuits 441 transmit the output signals received from the multiplexer circuits 411-418 and 421-428 through ESD circuits 442, bumps 432, and conductors in package substrate 403 to balls 433 for transmission through a circuit board.

FIG. 5 illustrates an example of a configurable logic integrated circuit (IC) 500 that can be, for example, the IC die disclosed herein with respect to any, some, or all of FIG. 1A, 1B, 2, 3, 4A, or 4B. As shown in FIG. 5, the programmable logic integrated circuit (IC) 500 includes a two-dimensional array of configurable functional circuit blocks, including configurable logic array blocks (LABs) 510 and other functional circuit blocks, such as random access memory (RAM) blocks 530 and digital signal processing (DSP) blocks 520. Functional blocks such as LABs 510 can include smaller programmable logic circuits (e.g., logic elements, logic blocks, or adaptive logic modules) that receive input signals and perform custom functions on the input signals to produce output signals.

In addition, programmable logic IC 500 can have input/output elements (IOEs) 502 for driving signals off of programmable logic IC 500 and for receiving signals from other devices. Input/output elements 502 can include parallel input/output circuitry, serial data transceiver circuitry, differential receiver and transmitter circuitry, or other circuitry used to connect one integrated circuit to another integrated circuit. As shown, input/output elements 502 can be located around the periphery of the chip. If desired, the programmable logic IC 500 can have input/output elements 502 arranged in different ways. For example, input/output elements 502 can form one or more columns, rows, or islands of input/output elements that may be located anywhere on the programmable logic IC 500.

The programmable logic IC 500 can also include programmable interconnect circuitry in the form of vertical routing channels 540 (i.e., interconnects formed along a vertical axis of programmable logic IC 500) and horizontal routing channels 550 (i.e., interconnects formed along a horizontal axis of programmable logic IC 500), each routing channel including at least one conductor to route at least one signal.

Note that other routing topologies, besides the topology of the interconnect circuitry depicted in FIG. 5, may be used. For example, the routing topology can include wires that travel diagonally or that travel horizontally and vertically along different parts of their extent as well as wires that are perpendicular to the device plane in the case of three dimensional integrated circuits. The driver of a wire can be located at a different point than one end of a wire.

Furthermore, it should be understood that embodiments disclosed herein can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Programmable logic IC 500 can contain programmable memory elements. Memory elements can be loaded with configuration data using input/output elements (IOEs) 502. Once loaded, the memory elements each provide a corresponding static control signal that controls the operation of an associated configurable functional block (e.g., LABs 510, DSP blocks 520, RAM blocks 530, or input/output elements 502).

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that can be controlled in this way include multiplexers (e.g., multiplexers used for forming routing paths in interconnect circuits), look-up tables, logic arrays, AND, OR, XOR, NAND, and NOR logic gates, pass gates, etc.

The programmable memory elements can be organized in a configuration memory array having rows and columns. A data register that spans across all columns and an address register that spans across all rows can receive configuration data. The configuration data can be shifted onto the data register. When the appropriate address register is asserted, the data register writes the configuration data to the configuration memory bits of the row that was designated by the address register.

In certain embodiments, programmable logic IC 500 can include configuration memory that is organized in sectors, whereby a sector can include the configuration RAM bits that specify the functions and/or interconnections of the subcomponents and wires in or crossing that sector. Each sector can include separate data and address registers.

The programmable logic IC of FIG. 5 is merely one example of an IC that can be used with embodiments disclosed herein. The embodiments disclosed herein can be used with any suitable integrated circuit or system. For example, the embodiments disclosed herein can be used with numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

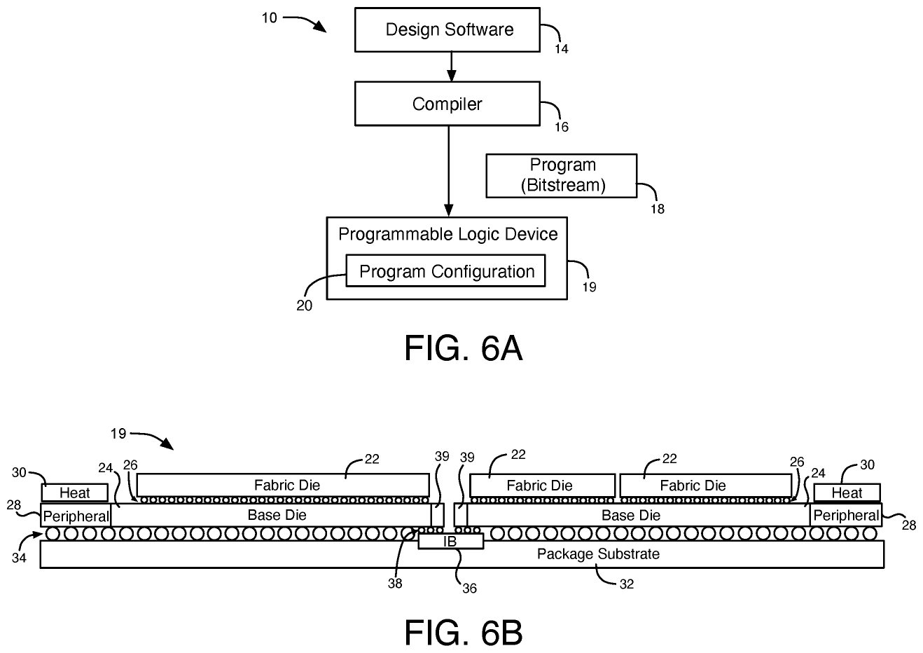

FIG. 6A illustrates a block diagram of a system 10 that can be used to implement a circuit design to be programmed into a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6B, but many others can be used, and it should be understood that this disclosure is intended to encompass any suitable programmable logic device where programmable logic fabric and fabric support circuitry are at least partially separated on different integrated circuit die.

FIG. 6B is a diagram that depicts an example of the programmable logic device 19 that includes three fabric die 22 and two base die 24 that are connected to one another via microbumps 26. In the example of FIG. 6B, at least some of the programmable logic fabric of the programmable logic device 19 is in the three fabric die 22, and at least some of the fabric support circuitry that operates the programmable logic fabric is in the two base die 24. For example, some of the circuitry of configurable IC 500 shown in FIG. 5 (e.g., LABs 510, DSP 520, and RAM 530) can be located in the fabric die 22 and some of the circuitry of IC 500 (e.g., input/output elements 502) can be located in the base die 24.

Although the fabric die 22 and base die 24 appear in a one-to-one relationship or a two-to-one relationship in FIG. 6B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

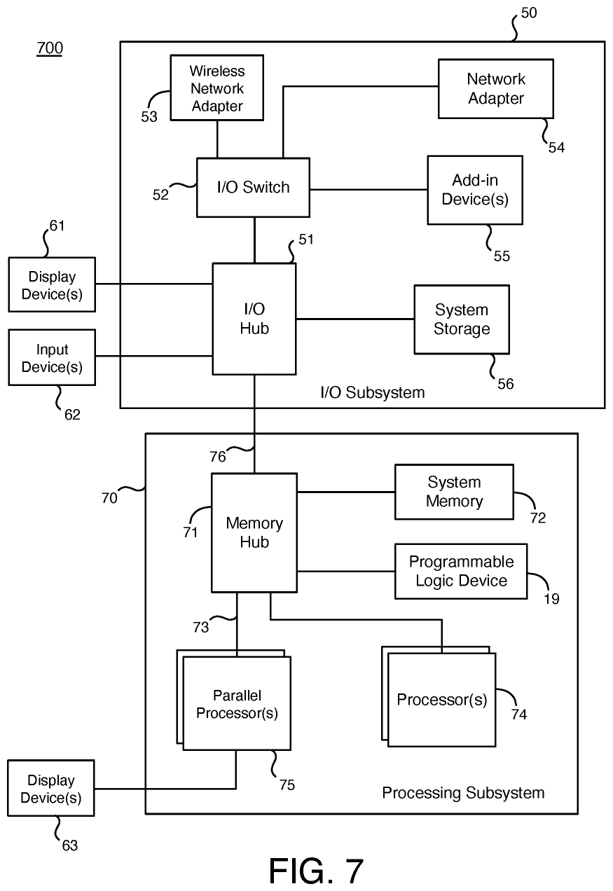

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is an active interposer device comprising: a first multiplexer circuit configurable to provide a first signal from a first integrated circuit to a first external terminal of the active interposer device in a first configuration of the active interposer device, wherein the first multiplexer circuit is further configurable to provide a second signal from a second integrated circuit to the first external terminal in a second configuration of the active interposer device, wherein the second integrated circuit is larger than the first integrated circuit, and wherein the active interposer device is configurable to couple the first integrated circuit or the second integrated circuit to a package substrate through the first external terminal.

In Example 2, the active interposer device of Example 1 further comprises: a first conductor coupled as a first fixed connection between a second external terminal of the active interposer device and a first input of the first multiplexer circuit for providing the first signal to the first multiplexer circuit; and a second conductor coupled as a second fixed connection between a third external terminal of the active interposer device and a second input of the first multiplexer circuit for providing the second signal to the first multiplexer circuit.

In Example 3, the active interposer device of any one of Examples 1-2 further comprises: an output buffer circuit coupled to an output of the first multiplexer circuit; and an electrostatic discharge circuit coupled between the output buffer circuit and the first external terminal.

In Example 4, the active interposer device of any one of Examples 1-3 further comprises: a second multiplexer circuit configurable to provide a third signal from the first integrated circuit to a second external terminal of the active interposer device in the first configuration, wherein the second multiplexer circuit is further configurable to provide a fourth signal from the second integrated circuit to the second external terminal in the second configuration.

In Example 5, the active interposer device of Example 4 further comprises: a first conductor coupled as a first fixed connection between a third external terminal of the active interposer device and a first input of the second multiplexer circuit for providing the third signal to the second multiplexer circuit; and a second conductor coupled as a second fixed connection between a fourth external terminal of the active interposer device and a second input of the second multiplexer circuit for providing the fourth signal to the second multiplexer circuit.

In Example 6, the active interposer device of any one of Examples 1-5, wherein the first configuration couples first input/output blocks of the first integrated circuit to connections on the package substrate in a first order, wherein the second configuration couples second input/output blocks of the second integrated circuit to the connections on the package substrate in the first order, and wherein the first input/output blocks have a reversed order relative to the second input/output blocks.

In Example 7, the active interposer device of any one of Examples 1-6 further comprises: a second multiplexer circuit configurable to provide a third signal from the first integrated circuit to the first external terminal in the first configuration, wherein the second multiplexer circuit is further configurable to provide an output signal of the first multiplexer circuit to the first external terminal in the second configuration.

In Example 8, the active interposer device of any one of Examples 1-7, wherein the first multiplexer circuit is further configurable to provide a third signal from the first integrated circuit to the first external terminal in the first configuration, and wherein the first multiplexer circuit comprises at least three data inputs for receiving the first, the second, and the third signals.

In Example 9, the active interposer device of any one of Examples 1-8, wherein the first signal is provided to a first input of the first multiplexer circuit from a first input/output circuit in a first memory interface in the first integrated circuit, and wherein the second signal is provided to a second input of the first multiplexer circuit from a second input/output circuit in a second memory interface in the second integrated circuit.

Example 10 is a method for migrating a package from a first integrated circuit to a second integrated circuit, the method comprising: configuring a first multiplexer circuit in an active interposer device to transmit a first signal from the first integrated circuit to a package substrate through a first conductive connection coupled to the active interposer device in a first configuration of the package; and configuring the first multiplexer circuit to transmit a second signal from the second integrated circuit to the package substrate through the first conductive connection in a second configuration of the package, wherein the second integrated circuit is larger than the first integrated circuit.

In Example 11, the method of Example 10 further comprises: configuring a second multiplexer circuit in the active interposer device to transmit a third signal from the first integrated circuit to the package substrate through a second conductive connection coupled to the active interposer device in the first configuration of the package; and configuring the second multiplexer circuit to transmit a fourth signal from the second integrated circuit to the package substrate through the second conductive connection in the second configuration of the package.

In Example 12, the method of any one of Examples 10-11 further comprises configuring a second multiplexer circuit to transmit an output signal of the first multiplexer circuit to the first conductive connection in the first configuration and in the second configuration.

In Example 13, the method of any one of Examples 10-12 further comprises providing the first signal through a first conductor coupled in a first fixed coupling in the active interposer device between a second conductive connection and a first input of the first multiplexer circuit; and providing the second signal through a second conductor coupled in a second fixed coupling in the active interposer device between a third conductive connection and a second input of the first multiplexer circuit.

In Example 14, the method of any one of Examples 10-13 further comprises: coupling first input/output circuits in the first integrated circuit to balls on a package substrate in a first order using the first multiplexer circuit in the first configuration; and coupling second input/output circuits in the second integrated circuit to the balls on the package substrate in the first order using the first multiplexer circuit in the second configuration, wherein the first input/output circuits are reversed relative to the second input/output circuits.

In Example 15, the method of any one of Examples 10-14 further comprises: buffering an output signal of the first multiplexer circuit using an output buffer circuit in the active interposer device to generate a buffered signal; and providing the buffered signal through an electrostatic discharge circuit to the first conductive connection.

Example 16 is an active interposer comprising: a first multiplexer circuit comprising a first input coupled to receive a first signal from a first integrated circuit through a first fixed connection in a first configuration of the active interposer, wherein the first multiplexer circuit further comprises a second input coupled to receive a second signal from a second integrated circuit through a second fixed connection in a second configuration of the active interposer, and wherein a first output signal of the first multiplexer circuit is provided to a first external terminal of the active interposer, wherein a first length of the first integrated circuit along a first surface coupled to the active interposer is longer than a second length of the second integrated circuit along a second surface coupled to the active interposer, and wherein the active interposer is configurable to be coupled to a package substrate through the first external terminal.

In Example 17, the active interposer of Example 16 further comprises: a second multiplexer circuit comprising a third input coupled to receive a third signal from the first integrated circuit through a third fixed connection in the first configuration, wherein the second multiplexer circuit further comprises a fourth input coupled to receive a fourth signal from the second integrated circuit through a fourth fixed connection in the second configuration, and wherein a second output signal of the second multiplexer circuit is provided to a second external terminal of the active interposer.

In Example 18, the active interposer of any one of Examples 16-17 further comprises: a second multiplexer circuit comprising a third input coupled to receive a third signal from the first integrated circuit through a third fixed connection in the first configuration, wherein the second multiplexer circuit further comprises a fourth input coupled to receive the first output signal of the first multiplexer circuit, and wherein a second output signal of the second multiplexer circuit is provided to the first external terminal.

In Example 19, the active interposer of any one of Examples 16-18, wherein the active interposer in the first configuration couples first input/output circuits in the first integrated circuit to a first order of conductive balls coupled to the package substrate, wherein the active interposer in the second configuration couples second input/output circuits in the second integrated circuit to the first order of the conductive balls, and wherein the second input/output circuits are reversed in a second order relative to a third order of the first input/output circuits.

In Example 20, the active interposer of any one of Examples 16-19, wherein the active interposer is migrated from a first integrated circuit package comprising the first integrated circuit to a second integrated circuit package comprising the second integrated circuit.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. An active interposer device comprising:
a first multiplexer circuit configurable to provide a first signal from a first integrated circuit to a first external terminal of the active interposer device in a first configuration of the active interposer device, wherein the first multiplexer circuit is further configurable to provide a second signal from a second integrated circuit to the first external terminal in a second configuration of the active interposer device, wherein the second integrated circuit is larger than the first integrated circuit, and wherein the active interposer device is configurable to couple the first integrated circuit or the second integrated circuit to a package substrate through the first external terminal.

2. The active interposer device of claim 1 further comprising:
a first conductor coupled as a first fixed connection between a second external terminal of the active interposer device and a first input of the first multiplexer circuit for providing the first signal to the first multiplexer circuit; and
a second conductor coupled as a second fixed connection between a third external terminal of the active interposer device and a second input of the first multiplexer circuit for providing the second signal to the first multiplexer circuit.

3. The active interposer device of claim 1 further comprising:
an output buffer circuit coupled to an output of the first multiplexer circuit; and
an electrostatic discharge circuit coupled between the output buffer circuit and the first external terminal.

4. The active interposer device of claim 1 further comprising:
a second multiplexer circuit configurable to provide a third signal from the first integrated circuit to a second external terminal of the active interposer device in the first configuration, wherein the second multiplexer circuit is further configurable to provide a fourth signal from the second integrated circuit to the second external terminal in the second configuration.

5. The active interposer device of claim 4 further comprising:
a first conductor coupled as a first fixed connection between a third external terminal of the active interposer device and a first input of the second multiplexer circuit for providing the third signal to the second multiplexer circuit; and
a second conductor coupled as a second fixed connection between a fourth external terminal of the active interposer device and a second input of the second multiplexer circuit for providing the fourth signal to the second multiplexer circuit.

6. The active interposer device of claim 1, wherein the first configuration couples first input/output blocks of the first integrated circuit to conductive balls on the package substrate in a first order, wherein the second configuration couples second input/output blocks of the second integrated circuit to the conductive balls on the package substrate in the first order, and wherein the first input/output blocks have a reversed order relative to the second input/output blocks.

7. The active interposer device of claim 1 further comprising:
a second multiplexer circuit configurable to provide a third signal from the first integrated circuit to the first external terminal in the first configuration, wherein the second multiplexer circuit is further configurable to provide an output signal of the first multiplexer circuit to the first external terminal in the second configuration.

8. The active interposer device of claim 1, wherein the first multiplexer circuit is further configurable to provide a third signal from the first integrated circuit to the first external terminal in the first configuration, and wherein the first multiplexer circuit comprises at least three data inputs for receiving the first, the second, and the third signals.

9. The active interposer device of claim 1, wherein the first signal is provided to a first input of the first multiplexer circuit from a first input/output circuit in a first memory interface in the first integrated circuit, and wherein the second signal is provided to a second input of the first multiplexer circuit from a second input/output circuit in a second memory interface in the second integrated circuit.

10. A method for migrating a package from a first integrated circuit to a second integrated circuit, the method comprising:
configuring a first multiplexer circuit in an active interposer to transmit a first signal from the first integrated circuit to a package substrate through a first conductive connection coupled to the active interposer in a first configuration of the package; and
configuring the first multiplexer circuit to transmit a second signal from the second integrated circuit to the package substrate through the first conductive connection in a second configuration of the package, wherein the second integrated circuit is larger than the first integrated circuit.

11. The method of claim 10 further comprising:
configuring a second multiplexer circuit in the active interposer to transmit a third signal from the first integrated circuit to the package substrate through a second conductive connection coupled to the active interposer in the first configuration of the package; and
configuring the second multiplexer circuit to transmit a fourth signal from the second integrated circuit to the package substrate through the second conductive connection in the second configuration of the package.

12. The method of claim 10 further comprising:
configuring a second multiplexer circuit to transmit an output signal of the first multiplexer circuit to the first conductive connection in the first configuration and in the second configuration.

13. The method of claim 10 further comprising:
providing the first signal through a first conductor coupled in a first fixed coupling in the active interposer between a second conductive connection and a first input of the first multiplexer circuit; and
providing the second signal through a second conductor coupled in a second fixed coupling in the active interposer between a third conductive connection and a second input of the first multiplexer circuit.

14. The method of claim 10 further comprising:
coupling first input/output circuits in the first integrated circuit to balls on the package substrate in a first order using the first multiplexer circuit in the first configuration; and
coupling second input/output circuits in the second integrated circuit to the balls on the package substrate in the first order using the first multiplexer circuit in the second configuration, wherein the first input/output circuits are reversed relative to the second input/output circuits.

15. The method of claim 10 further comprising:
buffering an output signal of the first multiplexer circuit using an output buffer circuit in the active interposer to generate a buffered signal; and
providing the buffered signal through an electrostatic discharge circuit to the first conductive connection.

16. An active interposer comprising:
a first multiplexer circuit comprising a first input coupled to receive a first signal from a first integrated circuit through a first fixed connection in a first configuration of the active interposer, wherein the first multiplexer circuit further comprises a second input coupled to receive a second signal from a second integrated circuit through a second fixed connection in a second configuration of the active interposer, wherein a first output signal of the first multiplexer circuit is provided to a first external terminal of the active interposer, wherein a first length of the first integrated circuit along a first surface coupled to the active interposer is longer than a second length of the second integrated circuit along a second surface coupled to the active interposer, and wherein the active interposer is configurable to be coupled to a package substrate through the first external terminal.

17. The active interposer of claim 16 further comprising:
a second multiplexer circuit comprising a third input coupled to receive a third signal from the first integrated circuit through a third fixed connection in the first configuration, wherein the second multiplexer circuit further comprises a fourth input coupled to receive a fourth signal from the second integrated circuit through a fourth fixed connection in the second configuration, and wherein a second output signal of the second multiplexer circuit is provided to a second external terminal of the active interposer.

18. The active interposer of claim 16 further comprising:
a second multiplexer circuit comprising a third input coupled to receive a third signal from the first integrated circuit through a third fixed connection in the first configuration, wherein the second multiplexer circuit further comprises a fourth input coupled to receive the first output signal of the first multiplexer circuit, and wherein a second output signal of the second multiplexer circuit is provided to the first external terminal.

19. The active interposer of claim 16, wherein the active interposer in the first configuration couples first input/output circuits in the first integrated circuit to a first order of conductive balls coupled to the package substrate, wherein the active interposer in the second configuration couples second input/output circuits in the second integrated circuit to the first order of the conductive balls, and wherein the second input/output circuits are reversed in a second order relative to a third order of the first input/output circuits.

20. The active interposer of claim 16, wherein the active interposer is migrated from a first integrated circuit package comprising the first integrated circuit to a second integrated circuit package comprising the second integrated circuit.
